(19) United States
(12) Patent Application Publication
(10) Pub. No.: US 2010/0170706 A1
(43) Pub. Date: Jul. 8, 2010

(54) ELECTRONIC MODULE AND METHOD FOR MANUFACTURING AN ELECTRONIC MODULE

(76) Inventors: Peter Kimmich, Schoenaich (DE); Quoc-Dat Nguyen, Reutlingen (DE)

Correspondence Address: KENYON & KENYON LLP, ONE BROADWAY, NEW YORK, NY, 10004, US

(21) Appl. No.: 12/452,104

(22) PCT Filed: Jun. 6, 2008
(86) PCT No.: PCT/EP2008/057123

§ 371 Date: Mar. 16, 2010

(30) Foreign Application Priority Data
Jun. 30, 2007 (DE) 10 2007 032 142.4

(51) Int. Cl. H05K 1/03; H05K 3/36; H05K 1/16; H05K 1/11

(52) U.S. Cl. 174/256; 29/830; 174/260; 174/261; 29/879

(57) ABSTRACT

An electronic module includes a first substrate having at least one electronic component, and a housing embedded in the substrate and designed as an injection molded housing or a transfer molded housing, and which includes electrical leads protruding from the housing, connected to the first substrate and designed as a pressed screen. At least one further second substrate provided with second electrical is embedded in the housing, the second leads being designed as a second pressed screen, and the two pressed screens being directly connected to each other in at least one location.

### BACKGROUND OF THE INVENTION

1. Field of the Invention

The present invention relates to an electronic module including a first substrate, which has least one electronic component, a housing embedded in the substrate and designed as an injection molded housing or a transfer molded housing, and including electrical leads protruding from the housing, which are connected to the first substrate and designed as a pressed screen.

2. Description of Related Art

An electronic module of this type is known. The substrate of the electronic module has at least one electronic power component and/or logic component. In terms of its outer contacting, the substrate is connected in an electrically conductive manner to leads which are designed as a pressed screen. To protect the electronic component-mounted substrate, the substrate is embedded in an injection molded housing or a transfer molded housing, together with the areas of the leads which are connected to the substrate. The modules extrusion coated in this manner are limited in terms of their footprint by the technical conditions present during shaping, for example the geometry of the injection mold, the filling heights and the flow behavior of the plastic used for extrusion coating, and by the spatial conditions. Expanding the electronic module onto multiple levels requires a complex structure having additional wiring levels, which substantially increases the number of manufacturing steps needed to manufacture the electronic module.

### BRIEF SUMMARY OF THE INVENTION

To increase component density with regard to a footprint of the electronic module, it is provided in accordance with the present invention that at least one further second substrate, which is provided with second electrical leads, is embedded in the housing, the second leads being designed as a second pressed screen, and the two pressed screens being directly connected to each other in at least one location. The first substrate and the first pressed screen form a first structural unit, and the second substrate and the second pressed screen form a second structural unit. The substrates situated on different levels are wired via the assigned pressed screens. These pressed screens therefore have the function of providing external contacting of the substrates and their electronic components and they may alternatively and/or additionally contact the substrates to each other. Furthermore, the pressed screens provide additional support for the assigned substrates. This is advantageous, in particular, before the substrates are embedded in the housing.

The housing both embeds and acts as an enclosure for the structural units. To design the housing as a transfer molded housing which embeds the structural units, the structural units are jointly enclosed by a molding material via resin transfer molding (RTM), the molding material subsequently forming the transfer molded housing. In particular, a thermosetting material or an elastomer material is used as the molding material for designing the housing. To design the housing as an injection molded housing which embeds the structural units, the structural units are enclosed, for example, using a known injection molding method.

It is also advantageously provided that at least one of the substrates is a ceramic substrate, in particular an LTCC substrate or a DBC substrate. Substrates of this type permit the use of higher currents, provide better insulation, and ensure operation within a greater temperature range than do conventional substrates. In particular, the ceramic substrate is a low-temperature co-fired ceramic (LTCC) substrate or a direct bonded copper (DBC) substrate.

In an advantageous embodiment of the present invention, it is provided that the connection between the substrates and the particular pressed screens is an electrical and/or a mechanical connection. The mechanical connection between the pressed screen and the substrate results in a stable, easy-to-manage structural unit. In particular, the substrate is designed as a circuit board having conductor tracks. For the purpose of external contacting of the circuit boards via the particular leads, the leads are preferably electrically connected to the conductor tracks.

According to a refinement of the present invention, it is provided that the connection between the substrates and the particular pressed screens is an adhesive connection and/or a bond connection and/or a solder connection. The adhesive connection is a mechanical connection which is electrically insulating but also electrically conductive (using conductive silver, for example). The adhesive connection results in a stable structural unit of the substrate and pressed screen. The bond connection is an electrical connection by which the substrate and pressed screen are flexibly connected to each other. The solder connection is both an electrical and a mechanical connection between the substrate and pressed screen. In particular, the electronic components are soldered or glued onto the substrates. An LTCC substrate including glued components is advantageously glued onto the pressed screen and electrically connected by bonding, and the components and a DBC substrate are mounted thereon for soldering to the components and the pressed screen. In particular, it is provided that two DBC substrates or two LTCC substrates or one LTCC substrate and one DBC substrate are combined to form an electronic module. In an advantageous embodiment of the present invention, it is provided that the connection between the first pressed screen and the second pressed screen is an electrically contacting connection.

It is advantageously provided that the electrically contacting connection is a weld, TOX and/or clamp connection. The pressed screens are connected by a joining process which enables electrical contacting.

The present invention also relates to a method for manufacturing an electronic module. It is provided that the electronic module includes a first and at least one second substrate, each of which has at least one electronic component, the method providing the following steps:
Connecting the first substrate to a first pressed screen to form a first structural unit, and connecting the second substrate to a second pressed screen to form a second structural unit;
Situating the structural units side by side, their pressed screens facing each other in at least one region;
Connecting the first and the second pressed screens in at least one location in the region; and
Jointly embedding the structural units in a housing which is designed as an injection molded housing or a transfer molded housing.

Connecting the substrates to the particular pressed screens results in easy-to-manage units. The structural units are situated, for example, side by side or on top of each other by stacking, so that their pressed screens face each other in at least one region. The pressed screen is preferably a pressed screen which completely surrounds the substrate and whose leads are formed in such a way that the substrates are situated opposite each other at a distance when the pressed screens face each other. According to this system of structural units, the two structural units are connected to each other by connecting the first and second pressed screens, thereby forming a complete unit. The structural units connected in this manner are jointly embedded into the housing. To design the housing as a transfer molded housing embedding the structural units, the structural units are jointly enclosed by a molding material via resin transfer molding (RTM), the molding material subsequently forming the transfer molded housing. In particular, a thermosetting material or an elastomer material is used as the molding material for forming the housing. During molding, a non-conductive material is injected directly around the structural units. The material is then cured, and the electronic module may be used as a compact, enclosed, and sturdy module. To design the housing as an injection molded housing embedding the structural units, the structural units are enclosed, for example, using a known injection molding method. At least one of the substrates is advantageously a ceramic substrate, in particular an LTCC substrate or a DBC substrate. The electronic components (power or logic components) are mounted on the substrates by soldering and/or gluing them thereto.

It is advantageously provided that the substrates are connected to the assigned pressed screens by gluing and/or bonding and/or soldering. The substrate is either glued onto the pressed screen and the electrical connections are bonded to the pressed screen, or the pressed screen is soldered onto the substrate together with the components. The LTCC substrate is advantageously glued onto the pressed screen together with the glued components and connected by bonding. The components and the pressed screen are advantageously mounted on a DBC substrate for soldering.

According to a refinement of the present invention, it is provided that the pressed screens are electrically contacted when they are connected. The electrical contacting causes the substrates to be wired together.

In an advantageous embodiment of the present invention, it is provided that the structural components situated side by side are accommodated in a cavity formed by mold segments of an injection mold or a transfer mold and embedded by injection molding or transfer molding. This injection mold or transfer mold includes, in particular, two mold segments designed as mold halves.

In particular, it is provided that at least one of the pressed screens has, in addition to the leads, at least one additional structure co-forming the cavity, which is (at least partially) removed after the structural units are embedded in the injection molded housing. Before it is removed, the additional structure positions the leads within the pressed screen and is designed, in particular, as a contiguous, circumferential structure which co-forms the cavity as a so-called “dam bar.” When situating the structural units side by side, the additional structures of the pressed screens, which are designed as dam bars, come to rest on top of each other. The mold halves of the injection mold or the resin transfer mold press on this dam bar, the cavity for the injection molded housing being hermetically and securely sealed. This seal geometry is very easy to produce, since it lies on one level.

Finally, it is advantageously provided that, to remove the additional structure, the latter is separated from the rest of the pressed screen by punching and/or laser cutting and/or shearing. After injection molding, in particular, an additional structure designed as a dam bar is separated between the leads by a separating operation (for example, punching, laser-cutting, shearing), so that the leads are electrically separated from each other. Alternatively, however, some connections may selectively remain connected between the two substrates to form the electrical connection, resulting in a shared circuit.

### BRIEF DESCRIPTION OF SEVERAL VIEWS OF THE DRAWING

FIG. 1 shows a top view of a structural unit including a component-mounted substrate and a pressed screen.

FIG. 2 shows a system of two structural units before they are connected.

FIG. 3 shows two structural units which are situated side by side and whose pressed screens face each other.

FIG. 4 shows the connected structural units according to FIGS. 2 and 3 in a transfer mold.

FIG. 5 shows an electronic module including structural units embedded in the transfer molded housing.

### DETAILED DESCRIPTION

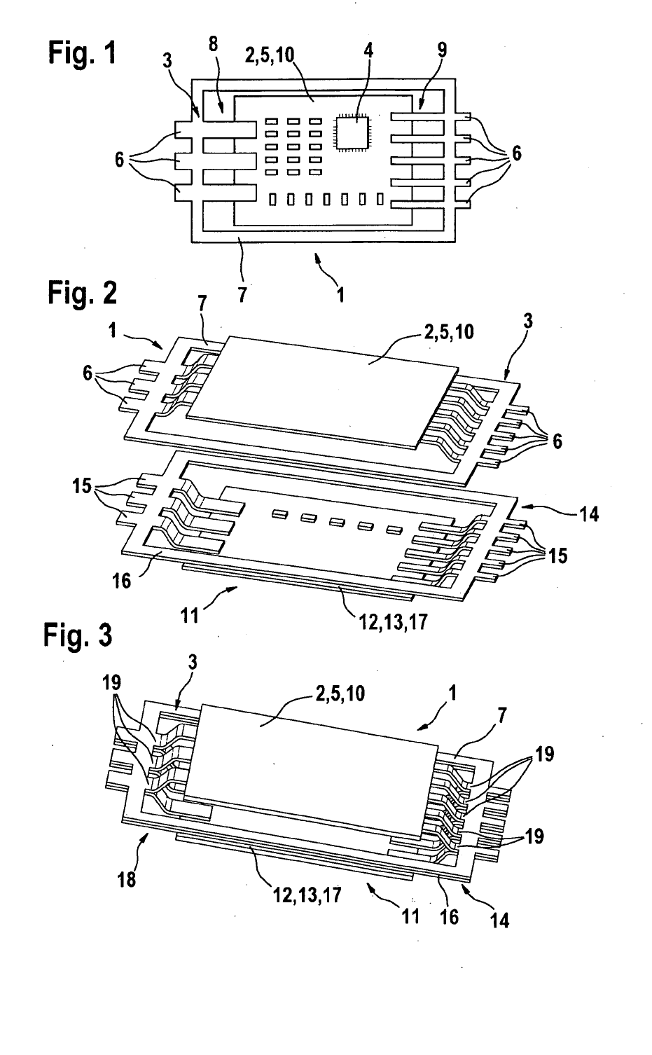

FIG. 1 shows a top view of a first structural unit 1, including a component-mounted first substrate 2 and a pressed screen 3. Substrate 2 has electronic components 4, only one of which is illustrated to simplify the representation. First substrate 2 is designed as a circuit board 5 having conductor tracks which are not illustrated. The conductor tracks are used to interconnect electronic components 4 within circuit board 5 and to provide contact surfaces for contacting first leads 6 of pressed screen 3. Explicitly illustrated component 4 is glued onto first substrate 2 and connected to the conductor paths (not shown) by bonding for the purpose of electrical contacting. Alternatively, electronic component 4 is glued onto first substrate 2. First pressed screen 3 has first leads 6 and a first additional structure 7 which connects first leads 6 and completely surrounds substrate 2 of finished structural unit 1. First leads 6 are situated within first structural unit 1 in such a way that three of first leads 6 are situated on one side 8 and four of leads 6 are situated on another side 9 of the first substrate opposite the one side 8. First substrate 2 is glued onto first pressed screen 3, and the contact surfaces of first substrate 2 designed as circuit board 5 are electrically connected to particular first leads 6 of first pressed screen 3 by bond connections which are not shown. As an alternative to connecting by gluing and bonding, pressed screen 3 is soldered onto substrate 2 together with components 4. First substrate 2 is designed as ceramic substrate 10.

FIG. 2 shows first structural unit 1 and a second structural unit 11 situated opposite each other. The second structural unit is structured in the same manner as first structural unit 1 and also has a second substrate 13 which is designed as a circuit board 12 and on which at least one electronic component 4 is mounted; the second structural unit also has a second pressed screen 14. Second pressed screen 14 has second leads 15 and an additional structure 16 surrounding second structural unit 11. The second substrate is also designed as ceramic substrate 17. Both structural units 1, 11 therefore each have one substrate 2, 13 designed as ceramic substrate 10, 17 and one pressed screen 3, 14 surrounding particular substrate 2, 13. Ceramic substrate 10 of first structural unit 1 is designed as an LTCC substrate having glued components 4, and it is glued onto pressed screen 5 of first structural unit 1. To produce the electrical connection, first leads 6 of first pressed screen 3 are electrically connected to contacts on first substrate 2 by bond connections. Ceramic substrate 17 of second structural unit 11 is a DBC substrate on which electrical components 4 and corresponding second pressed screen 14 are mounted and which is subsequently soldered. In second structural unit 11, therefore, a solder connection is produced between second pressed screen 14 and second substrate 13. In both structural units 1, 11, leads 6, 15 are crimped, resulting in an additional structure level of particular additional structure 7, 16 which is situated at a distance from a substrate level of particular substrate 2, 13. Structural units 1, 11 are situated opposite each other in such a way that they face each other by their particular additional structure levels and their components 4.

FIG. 3 shows a system of structural units 1, 11, in which additional structures 7, 16, which correspond to each other and contiguously surround their particular substrates 2, 13, are positioned on top of each other. Structural units 1, 11 are situated side by side in such a way that their pressed screens 3, 14 face each other circumferentially in region 18 of their particular additional structures 7, 16. Structural units 1, 11 situated in this manner are subsequently connected to each other in at least one location 19 by their pressed screens 3, 14 in the region of circumferential additional structures 7, 16. In this connection, pressed screens 3, 14 are electrically contacted to each other.

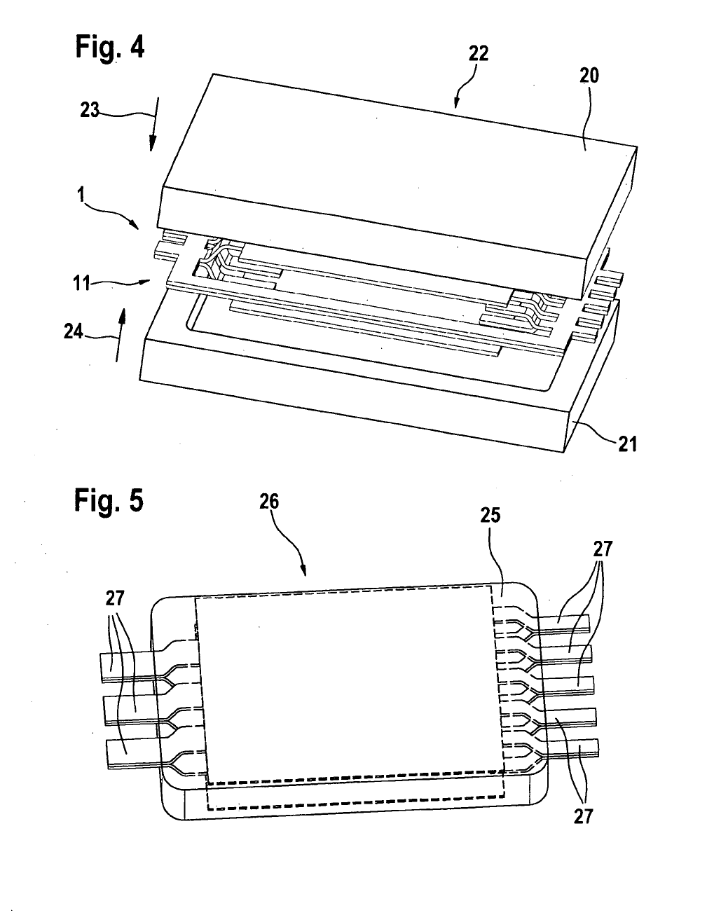

FIG. 4 shows the two interconnected structural units 1, 11 in two mold segments 20, 21 of an injection mold 22, which are designed as mold halves. Both mold segments 20, 21 are pressed on both sides against stacked, circumferential additional structures 7, 16 (mold segment 20 in the direction of arrow 23, mold segment 21 in the direction of arrow 24). Together with circumferential additional structures 7, 16, mold segments 20, 21 form a cavity surrounding structural units 1, 11, only the parts of leads 6, 15 situated outside additional structures 7, 16 protruding from this cavity.

The parts of structural units 1, 11 located within the cavity are then extrusion-coated with non-conductive material, so that, after curing, a thereby produced transfer molded housing 25 of finished electronic module 26 shown in FIG. 5 holds together and provides support. After the transfer molding process, parts of additional structures 7, 16 between lead elements 27 formed by leads 6, 15 are removed. For this purpose, these parts are separated from the rest of particular pressed screen 3, 14 by a separating operation, for example by punching, laser cutting or shearing. However, parts of additional structures 7, 16 may also remain selectively connected for form an electrical connection.

FIGS. 1 through 5 show the sequence of individual method steps in the manufacture of an electronic module 26 shown in FIG. 5.

Leads 27 of electronic module 26 may be provided with special geometries for further connection to the outside:
Press-in system for circuit boards or press-in system in pressed screens 3, 14;
Insulation displacement terminals for connection to wired components 4 or pressed screens 3, 14;
Designed as pins for conventional plug connectors or a means for screwing on other electrical components or wires.

1-12. (canceled)

13. An electronic module, comprising:
a first substrate having at least one electronic component;
a housing embedded in the first substrate and configured as one of an injection molded housing or a transfer molded housing;
a first pressed screen including first electrical leads, wherein the first electrical leads protrude from the housing and are connected to the first substrate;
at least one second substrate;
a second pressed screen including second electrical leads, wherein the second pressed screen is connected to the at least one second substrate, and wherein the at least one second substrate is embedded in the housing, and wherein the first and second pressed screens are directly connected to each other in at least one location.

14. The electronic module as recited in claim 13, wherein at least one of the first and second substrates is a ceramic substrate.

15. The electronic module as recited in claim 14, wherein the connections (a) between the first pressed screen and the first substrate, and (b) between the second pressed screen and the second substrate, are electrical and mechanical connections.

16. The electronic module as recited in claim 15, wherein the connections (a) between the first pressed screen and the first substrate, and (b) between the second pressed screen and the second substrate, are at least one of an adhesive connection, a bond connection and a solder connection.

17. The electronic module as recited in claim 15,
wherein the connection between the first pressed screen and the second pressed screen provides an electrical contact between the first and second pressed screens.

18. The electronic module as recited in claim 17, wherein the electrical contact between the first and second pressed screens is one of a weld, TOX or clamp connection.

19. A method for manufacturing an electronic module, comprising:
connecting a first substrate having an electronic component to a first pressed screen to form a first structural unit;
connecting a second substrate having an electronic component to a second pressed screen to form a second structural unit;
situating the first and second structural units next to each other such that the first and second pressed screens face each other in at least one region;
connecting the first and the second pressed screens in the at least one region; and
jointly embedding the first and second structural units in a housing configured as one of an injection-molded or transfer-molded housing.

20. The method as recited in claim 19, wherein the first and second substrates are connected to the corresponding first and second pressed screens by at least one of gluing, bonding and soldering.

21. The method as recited in claim 20, wherein the first and second pressed screens are electrically contacted with one another.

22. The method as recited in claim 21, wherein the first and second structural units situated side by side are accommodated in a cavity formed by mold segments of an injection mold and are embedded by injection molding.

23. The method as recited in claim 22, wherein at least one of the first and second pressed screens has electrical leads and at least one additional structure co-forming the cavity, wherein the additional structure is at least partially removed after the first and second structural units are embedded in the injection molded housing.

24. The method as recited in claim 23, wherein, the additional structure is at least partially removed by separating the additional structure from the at least one of the first and second pressed screens by at least one of punching, laser cutting and shearing.
